(19) United States
(12) Patent Application Publication
(10) Pub. No.: US 2024/0372037 A1
(43) Pub. Date: Nov. 7, 2024

(54) SEMICONDUCTOR SUBSTRATE AND SEMICONDUCTOR THIN FILM DEPOSITION APPARATUS

(71) Applicant: KOREA UNIVERSITY RESEARCH AND BUSINESS FOUNDATION, Seoul (KR)

(72) Inventors: In Hwan LEE, Seoul (KR); Ho Ki SON, Seoul (KR)

(73) Assignee: KOREA UNIVERSITY RESEARCH AND BUSINESS FOUNDATION, Seoul (KR)

(21) Appl. No.: 18/688,117

(22) PCT Filed: Aug. 22, 2022
(86) PCT No.: PCT/KR2022/012488

§ 371 Date: Feb. 29, 2024

(30) Foreign Application Priority Data
Aug. 31, 2021 (KR) 10-2021-0115764
Aug. 19, 2022 (KR) 10-2022-0104180

(51) Int. Cl. H01L 33/32; H01L 33/16

(52) U.S. Cl. CPC H01L 33/32; H01L 33/16

(57) ABSTRACT

The semiconductor substrate of the present invention may comprise a substrate and a semiconductor layer arranged on the substrate. Additional energy is supplied to sputtering in a thin film growth process step so that the semiconductor layer can be deposited. The additional energy can be at least one from among an ion beam, an electron beam, plasma, ultraviolet rays, a laser, and an LED light source. For example, the substrate can be a glass substrate, and the semiconductor layer can be a nitride semiconductor layer having a single-crystal plane. The semiconductor layer can be deposited by means of ion beam sputtering using the ion beam as the additional energy.

### TECHNICAL FIELD

The present invention relates to a semiconductor substrate and a semiconductor thin film deposition apparatus. More particularly, the present invention relates to a semiconductor substrate and a semiconductor thin film deposition apparatus that are capable of reducing a thin film deposition temperature using ion beam sputtering and growing a nitride semiconductor layer having a single crystal plane from a thin film growth stage.

### BACKGROUND ART

Since nitride semiconductors, such as GaN semiconductors, have excellent physical and chemical properties, nitride semiconductors are expected to be a material that can advance the electronics industry. That is, unlike conventional Si semiconductors or GaAs compound semiconductors, GaN has a direct transition band gap structure, and the band gap can be adjusted from 0.8 to 6.2 eV through alloying with In or Al. Thus, GaN has great utility as an optical device such as light-emitting diodes (LEDs). In addition, GaN has a high breakdown voltage and is stable even at high temperatures, so GaN is useful in various fields such as high-power devices and high-temperature electronic devices that cannot be implemented with existing materials. For example, GaN can be used in TVs having full-color displays, large electronic signs, traffic lights, light sources in optical recording media, and high-output transistors in automobile engines.

Conventional representative technologies for forming nitride semiconductor single crystals include metal organic CVD (MOCVD) and molecular beam epitaxy (MBE) methods. To obtain a nitride semiconductor thin film using these methods, a substrate must be kept heated to about 1,000 to 1,100° C. Accordingly, the substrate on which the nitride semiconductor thin film is formed was limited to single crystal sapphire (Al₂O₃), silicon (Si), and silicon carbide (SiC), which have relatively high strain temperatures. However, in the case of sapphire substrates, it is difficult to produce large-area wafers larger than 6 inches, and the high production cost makes it difficult to implement large-area displays such as large TVs. In addition, in the case of sapphire substrates, deterioration problems such as distortion of a substrate may occur due to thermal expansion of the substrate, and the thin film may be damaged due to differences in the lattice constant and thermal expansion coefficient between a nitride semiconductor thin film formed on the substrate and the substrate.

In particular, when growing a nitride semiconductor thin film on a single crystal sapphire substrate using the MOCVD method, in a micro-LED display manufacturing process, a process of transferring LEDs to a second substrate, such as a glass substrate, is essential. When LED transfer is required, the cost of the LED manufacturing and transfer process increases significantly, thus significantly increasing the production cost of a display. As a result, the production cost of large TVs using light-emitting devices such as micro LEDs increases.

Accordingly, a nitride semiconductor structure and a manufacturing method that can grow nitride semiconductor thin films on substrates other than sapphire substrates have been proposed. For example, in Korean Patent Application Publication No. 10-2009-0081879 “METHOD OF MANUFACTURING NITRIDE SEMICONDUCTOR SUBSTRATE”, a method of manufacturing a nitride semiconductor by growing aluminum nitride with a single crystal plane using an Si substrate with a single crystal plane is proposed. For example, in Korean Patent Application Publication No. 10-2012-0076000 “ROOM TEMPERATURE SPUTTERING METHOD OF GROUP III NITRIDE BY APPLYING PULSED DC BIAS SUBSTRATE”, a method of manufacturing a nitride substrate with improved crystallinity by reducing a growth temperature through room temperature sputtering using a substrate bias is proposed.

However, there have been no research results on growing a gallium nitride semiconductor thin film with a single crystal plane on an amorphous or polycrystalline substrate.

### DISCLOSURE

### Technical Problem

Therefore, the present invention has been made in view of the above problems, and it is one object of the present invention to provide a semiconductor substrate capable of reducing a thin film growth temperature compared to conventional processes by providing sputtering ion beams during a thin film growth process.

It is another object of the present invention to provide a semiconductor substrate manufacturing method capable of producing a micro-LED display without a separate transfer process by directly depositing a nitride semiconductor layer on a substrate such as glass, a polyimide polymer film, or stainless steel.

However, the technical problems that the present invention seeks to solve are not limited to the description, and can be expanded in various ways without departing from the idea and scope of the present invention.

### Technical Solution

In accordance with one aspect of the present invention, provided is a semiconductor substrate including a substrate and a semiconductor layer disposed on an upper portion of the substrate, wherein the semiconductor layer is deposited by supplying additional energy through sputtering in a thin film growth process step, wherein the additional energy includes at least one of ion beams, electron beams, plasma, ultraviolet lights, lasers, and LED light.

In one embodiment, the substrate may be a glass substrate, the semiconductor layer may be a nitride semiconductor layer having a single crystal plane, and the semiconductor layer may be deposited by ion beam sputtering, which uses the ion beams as the additional energy.

In one embodiment, the ion beam sputtering may be performed using at least one of helium (He), neon (Ne), argon (Ar), krypton (Kr), xenon (Xe), radon (Rn), hydrogen (H₂), oxygen (O₂), nitrogen (N₂), chlorine (Cl₂), and ammonia (NH₃).

In one embodiment, a sputtering target used for the ion beam sputtering may include gallium (Ga) or gallium nitride (GaN).

In one embodiment, in the thin film growth process step, a deposition temperature of the semiconductor layer may be 600° C. or lower.

In one embodiment, the substrate may include at least one of an amorphous substrate and a polycrystalline substrate.

In one embodiment, the substrate may include at least one of a glass substrate, a quartz substrate, a stainless steel substrate, and a polymer substrate.

In one embodiment, the semiconductor layer may be a silicon semiconductor layer having any one of polycrystalline, microcrystalline, and nanocrystalline crystal structures.

In one embodiment, the semiconductor layer may be an InGaZnO-based oxide semiconductor layer.

In one embodiment, the semiconductor layer may be a CuInSe₂-based group 1-3-5 compound semiconductor layer.

In one embodiment, the semiconductor substrate may further include a middle layer disposed between the substrate and the semiconductor layer and consisting of at least one of aluminum nitride and zinc oxide.

In accordance with another aspect of the present invention, provided is a semiconductor thin film deposition apparatus including a thin film deposition device for growing a nitride semiconductor layer having a single crystal plane on an upper portion of a substrate through sputtering; and an energy supplier for supplying additional energy of at least one of ion beams, electron beams, plasma, ultraviolet lights, lasers, and LED light to the substrate, wherein the energy supplier supplies the additional energy to the substrate while the thin film deposition device grows the nitride semiconductor layer on an upper portion of the substrate.

### Advantageous Effects

In the case of the semiconductor substrate according to embodiments of the present invention, sputtering ion beams are supplied as additional energy to the thin film growth process, and a portion of energy required for thin film deposition is provided from the kinetic energy of ion beams, so the temperature of thin film growth may be lowered compared to the conventional processes. According to the present invention, glass substrates, quartz substrates, stainless steel substrates, and polymer substrates with a strain temperature of 650° C. lower may be used in the process of forming the semiconductor layer.

In addition, according to the present invention, ion beam sputtering may be used to grow a nitride semiconductor thin film with a single crystal plane from the thin film growth stage, thereby simplifying the production process of the nitride semiconductor substrate and reducing the manufacturing cost of the nitride semiconductor substrate.

In particular, in the semiconductor substrate according to embodiments of the present invention, a nitride semiconductor layer may be deposited directly on a glass substrate, so light-emitting element chip production and transfer process may be omitted in the micro-LED display production process. Accordingly, as the production costs of LED chip manufacturing and transfer process are reduced, the manufacturing cost of large TVs containing light-emitting elements such as micro LEDs may be significantly reduced.

However, the effects of the present invention are not limited to the above-described effects, and may be broadly extended without departing from the spirit and scope of the present invention.

### DESCRIPTION OF DRAWINGS

FIG. 1 is a cross-sectional view of a semiconductor substrate according to embodiments of the present invention.

FIG. 2 is a flowchart explaining a method of manufacturing the semiconductor substrate of FIG. 1.

FIG. 3 illustrates a semiconductor thin film deposition apparatus for manufacturing the semiconductor substrate of FIG. 1.

FIG. 4 illustrates depositing a semiconductor layer in a thin film growth process step.

FIG. 5 is a diagram showing one embodiment of the thin film growth process step.

FIG. 6 is a diagram showing an example in which the semiconductor substrate of FIG. 1 is manufactured directly on a display backplane without a transfer process.

FIG. 7 is a cross-sectional view of a semiconductor substrate having a middle layer.

FIG. 8 is a flowchart showing a method of manufacturing the semiconductor substrate of FIG. 7.

FIG. 9 includes XRD analysis graphs comparing the growth of a semiconductor layer on a sapphire substrate depending on the presence or absence of additional energy.

FIG. 10 includes optical images of semiconductor layers corresponding to the XRD analysis graphs of FIG. 9.

FIG. 11 includes XRD analysis graphs comparing the growth of a semiconductor layer on a glass substrate depending on the presence or absence of additional energy.

FIG. 12 includes optical images of semiconductor layers corresponding to the XRD analysis graphs of FIG. 11.

FIG. 13 includes graphs comparing the semiconductor layer of the method according to the present invention in which additional energy is applied through the sputtering method and the semiconductor layer of the conventional MOCVD method.

### BEST MODE

Specific structural and functional descriptions of embodiments according to the concept of the present invention disclosed herein are merely illustrative for the purpose of explaining the embodiments according to the concept of the present invention. Furthermore, the embodiments according to the concept of the present invention can be implemented in various forms and the present invention is not limited to the embodiments described herein.

The embodiments according to the concept of the present invention may be implemented in various forms as various modifications may be made. The embodiments will be described in detail herein with reference to the drawings. However, it should be understood that the present invention is not limited to the embodiments according to the concept of the present invention, but includes changes, equivalents, or alternatives falling within the spirit and scope of the present invention.

It should be understood that, although the terms first, second, third etc. may be used herein to describe various elements, these elements should not be limited by these terms. These terms are only used to distinguish one element from another element. For example, a first element may be termed a second element and a second element may be termed a first element without departing from the teachings of the present invention.

It should be understood that when an element is referred to as being “connected to” or “coupled to” another element, the element may be directly connected or coupled to the other element or intervening elements may be present. In contrast, when an element is referred to as being “directly connected to” or “directly coupled to” another element, there are no intervening elements present. Other words used to describe the relationship between elements or layers should be interpreted in a like fashion (e.g., “between,” versus “directly between,” “adjacent,” versus “directly adjacent,” etc.).

The terms used in the present specification are used to explain a specific exemplary embodiment and not to limit the present inventive concept. Thus, the expression of singularity in the present specification includes the expression of plurality unless clearly specified otherwise in context. Also, terms such as “include” or “comprise” should be construed as denoting that a certain characteristic, number, step, operation, constituent element, component or a combination thereof exists and not as excluding the existence of or a possibility of an addition of one or more other characteristics, numbers, steps, operations, constituent elements, components or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, preferred embodiments of the present invention will be described in detail with reference to the accompanying drawings. However, the scope of the present invention is not limited by these embodiments. Like reference numerals in the drawings denote like elements.

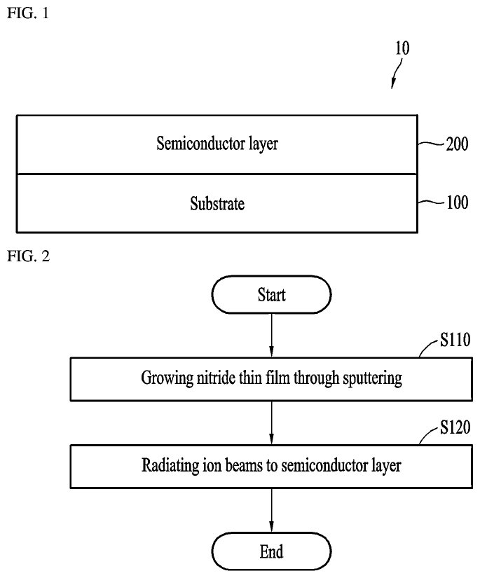

FIG. 1 is a cross-sectional view of a semiconductor substrate 10 according to embodiments of the present invention, and FIG. 2 is a flowchart showing a method of manufacturing the semiconductor substrate 10 of FIG. 1.

Referring to FIG. 1, the semiconductor substrate 10 according to embodiments of the present invention may include a substrate 100 and the semiconductor layer 200 disposed on the upper portion of the substrate 100.

In one embodiment, the semiconductor layer 200 may be a nitride semiconductor layer having a single crystal plane.

However, the semiconductor layer 200 of the present invention described later is not limited to the nitride semiconductor layer.

For example, the semiconductor layer 200 may be a silicon semiconductor layer having any one of polycrystalline, microcrystalline, and nanocrystalline crystal structures.

For example, the semiconductor layer 200 may be an InGaZnO-based oxide semiconductor layer.

For example, the semiconductor layer 200 may be a CuInSe₂-based group 1-3-5 compound semiconductor layer.

Representative conventional technologies for depositing the semiconductor layer 200 include the metal organic CVD (MOCVD) method and the molecular beam epitaxy (MBE) method. To deposit the semiconductor layer 200 by these conventional methods, the substrate 100 must be kept heated to a temperature of approximately 1,000° C. to 1,100° C.

Accordingly, when the metal organic CVD (MOCVD) method or the molecular beam epitaxy (MBE) method is used, the substrate 100 on which the semiconductor thin film is formed is limited to single crystal sapphire (Al₂O₃), silicon (Si), and silicon carbide (SiC), which have relatively high strain temperatures.

However, it is difficult to produce large-area wafers larger than 12 inches using the substrate 100, and it is difficult to implement large-area displays such as large TVs due to high production costs.

In addition, when growing a semiconductor thin film on a sapphire substrate, a process of transferring a light-emitting element to a glass substrate is essential in a micro LED manufacturing process, so the production cost of micro LEDs significantly increases due to the transfer process.

To solve this problem, the semiconductor layer 200 included in the semiconductor substrate 10 according to the present invention may be deposited by applying additional energy in the sputtering method.

Referring to FIG. 2, the semiconductor substrate 10 of the present invention may be manufactured through step S110 of growing a nitride thin film through sputtering and step S120 in which the semiconductor layer 200 is irradiated with ion beams.

In one embodiment, step S110 of growing a nitride thin film and step S120 in which the semiconductor layer 200 is irradiated with ion beams may be performed at the same time.

That is, in the thin film growth process step, the semiconductor layer 200 may be deposited by simultaneously supplying additional energy through sputtering.

The additional energy may be at least one of ion beams, electron beams, plasma, ultraviolet lights, lasers, and LED light.

For example, the semiconductor substrate 10 of the present invention may be provided with sputtering ion beams in the thin film growth process.

In this case, since a portion of energy required for deposition of the semiconductor layer 200 is provided by the kinetic energy of ion beams, the semiconductor substrate 10 may reduce a thin film growth temperature compared to the conventional process.

The substrate 100 may be at least one of an amorphous substrate and a polycrystalline substrate.

For example, the substrate 100 may be at least one of a glass substrate, a quartz substrate, a stainless steel substrate, and a polymer substrate.

According to the present invention, the glass substrate 100, the quartz substrate 100, the stainless steel substrate 100, and the polymer substrate 100 with a strain temperature of 650° C. or less may be used to deposit a gallium nitride thin film having a single crystal plane.

In one embodiment, the substrate 100 may be a glass substrate, and the semiconductor layer 200 may be a nitride semiconductor layer having a single crystal plane.

For example, on the glass substrate, a nitride semiconductor layer may be deposited by ion beam sputtering using ion beams as the additional energy.

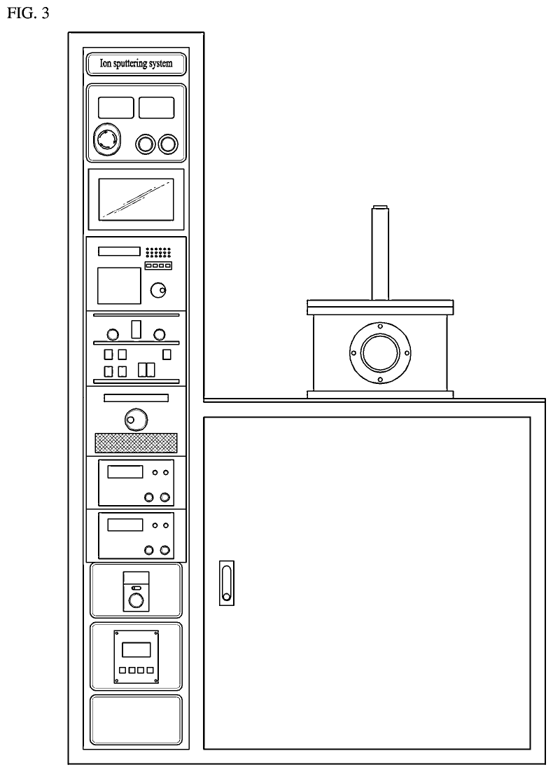

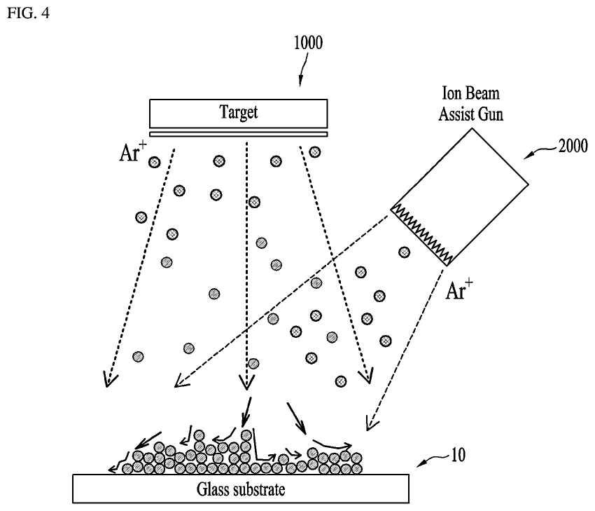

FIG. 3 illustrates a semiconductor thin film deposition apparatus for manufacturing the semiconductor substrate 10 of FIG. 1, and FIG. 4 illustrates depositing a semiconductor layer 200 in the thin film growth process step.

Referring to FIG. 3, the semiconductor substrate 10 of the present invention may be manufactured using the semiconductor thin film deposition apparatus.

The semiconductor thin film deposition apparatus may include a plurality of components for manufacturing the semiconductor substrate 10.

For example, the semiconductor thin film deposition apparatus may include a thin film deposition device 1000 and an energy supplier 2000.

The thin film deposition device 1000 may grow a nitride semiconductor layer having a single crystal plane on the upper portion of the substrate 100 by sputtering.

The energy supplier 2000 may supply at least one of ion beams, electron beams, plasma, ultraviolet lights, lasers, and LED light as the additional energy to the substrate 100.

For example, the energy supplier 2000 may supply the additional energy to the substrate 100 while the thin film deposition device 1000 grows the nitride semiconductor layer on the upper portion of the substrate 100.

As shown in FIG. 4, the semiconductor thin film deposition apparatus may deposit the semiconductor layer 200 on the substrate 100 using ion beam sputtering.

For example, the thin film deposition device 1000 may grow a nitride semiconductor layer having a single crystal plane on the upper portion of the substrate 100 by sputtering, and at the same time, the energy supplier 2000 may supply ion beams to the substrate 100.

The sputtering target used for the ion beam sputtering may include gallium (Ga) or gallium nitride (GaN).

For example, the thin film deposition device 1000 may grow a nitride semiconductor layer using at least one of gallium (Ga) and gallium nitride (GaN) as a sputtering target.

In the ion beam sputtering, at least one of helium (He), neon (Ne), argon (Ar), krypton (Kr), xenon (Xe), radon (Rn), hydrogen (H₂), oxygen (O₂), nitrogen (N₂), chlorine (Cl₂), and ammonia (NH₃) may be used.

For example, the energy supplier 2000 may supply ion beams including at least one of helium (He), neon (Ne), argon (Ar), krypton (Kr), xenon (Xe), radon (Rn), hydrogen (H₂), oxygen (O₂), nitrogen (N₂), chlorine (Cl₂), and ammonia (NH₃) to the substrate 100.

In one embodiment, the deposition temperature of the semiconductor layer 200 may be below 600° C. in the thin film growth process step.

For example, the semiconductor layer 200 may be deposited at a rate of 300 nm per hour at a temperature below 600° C. by the ion beam sputtering.

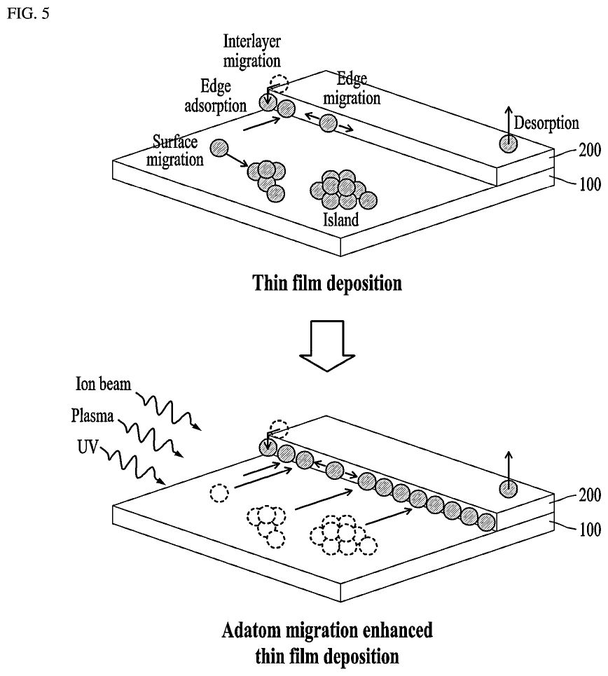

FIG. 5 is a diagram showing one embodiment of the thin film growth process step.

As shown in FIG. 5, the semiconductor thin film deposition apparatus may provide some of energy required for depositing the semiconductor layer 200 as additional energy (e.g., ion beam energy, plasma energy, and UV energy) rather than thermal energy.

That is, the semiconductor thin film deposition apparatus may improve the mobility of atoms and molecules that reach the semiconductor layer 200 on the substrate by supplying additional energy of at least one of ion beams, electron beams, plasma, ultraviolet lights, lasers, and LED light to the semiconductor layer 200.

For example, as shown in FIG. 5, a sputtering target output from the thin film deposition device 1000 may be deposited on the semiconductor layer 200 by absorbing the kinetic energy of ions output from the energy supplier 2000 instead of thermal energy.

In this way, when the surface mobility of gallium and nitrogen particles being grown is increased by the kinetic energy of ions, energy required for thin film crystal growth is relatively reduced, so the temperature of the substrate 100 may be kept low.

Accordingly, the semiconductor thin film deposition apparatus minimizes thermal energy applied to the substrate 100, thus reducing the thin film growth temperature of the semiconductor substrate 10 compared to the conventional processes.

In addition, since the semiconductor substrate 10 uses ion beam sputtering to grow a nitride semiconductor thin film having a single crystal plane from the thin film growth stage, the production process of the semiconductor substrate 10 may be simplified, and the manufacturing cost of the semiconductor substrate 10 may be reduced.

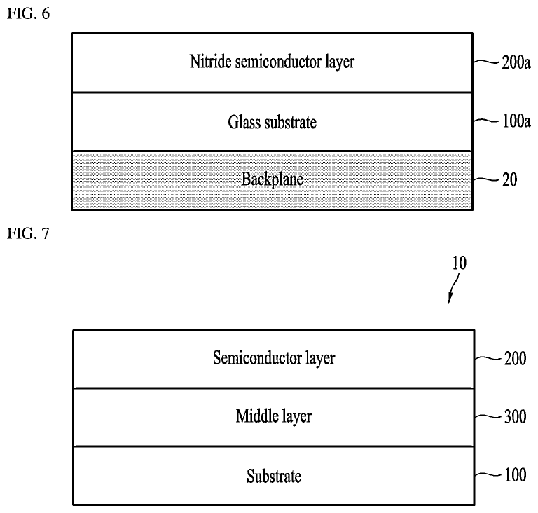

FIG. 6 is a diagram showing an example in which the semiconductor substrate 10 of FIG. 1 is manufactured directly on a display backplane 20 without a transfer process.

In FIG. 6, the substrate 100 may be a glass substrate, and the semiconductor layer 200 may be a nitride semiconductor layer having a single crystal plane.

Referring to FIG. 6, the semiconductor substrate 10 may be manufactured directly on the backplane 20.

Specifically, the semiconductor substrate 10 may be provided with sputtering ion beams in the nitride thin film growth process, and a portion of energy required for deposition of the semiconductor layer 200 may be provided from the kinetic energy of ion beams.

Accordingly, a nitride semiconductor layer 200a may be deposited on a glass substrate 100a having a strain temperature of 650° C. or lower.

As shown in FIG. 6, when the nitride semiconductor layer 200a is deposited directly on the glass substrate 100a, unlike the case where the nitride semiconductor layer 200a is deposited on a sapphire substrate, the semiconductor substrate 10 may be manufactured directly on the backplane 20.

According to the method of manufacturing the semiconductor substrate 10 of the present invention, a light-emitting element chip production process and a light-emitting element transfer process may be omitted in a micro-LED display production process.

Accordingly, when the present invention is applied, since production costs due to light-emitting element chip production and transfer process are reduced, the manufacturing cost of large displays containing micro LEDs, such as large-area 4K Micro-LED TVs, may be dramatically reduced.

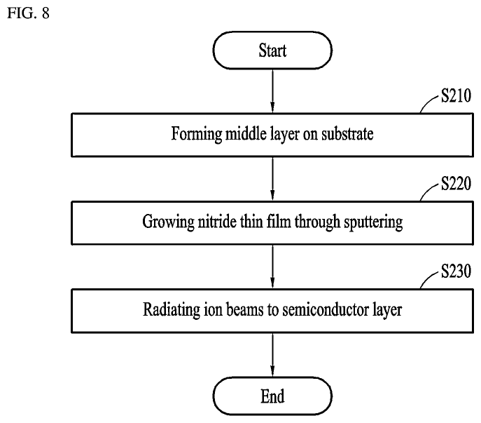

FIG. 7 is a cross-sectional view of the semiconductor substrate 10 including a middle layer 300, and FIG. 8 is a flowchart showing the method of manufacturing the semiconductor substrate 10 of FIG. 7.

Referring to FIG. 7, the semiconductor substrate 10 may further include the middle layer 300 disposed between the substrate 100 and the semiconductor layer 200 and consisting of at least one of aluminum nitride and zinc oxide.

As shown in FIG. 8, the semiconductor substrate 10 of the present invention may be manufactured through step S210 of forming the middle layer 300 on the substrate 100, step S220 of growing a nitride thin film by sputtering, and step S230 in which the semiconductor layer 200 is irradiated with ion beams.

That is, the semiconductor substrate 10 may be manufactured in a process sequence in which the middle layer 300 is deposited on the upper portion of the substrate 100 and then a nitride semiconductor layer is deposited on the upper portion of the middle layer 300.

The substrate 100 may be an amorphous substrate or a polycrystalline substrate. For example, the substrate 100 may be at least one of a glass substrate, a quartz substrate, a stainless steel substrate, and a polymer substrate.

The middle layer 300 may be disposed between the substrate 100 and the semiconductor layer 200.

The middle layer 300 may be a layer for facilitating deposition of the semiconductor layer 200.

For example, the middle layer 300 may be composed of aluminum nitride or zinc oxide, which allows the nitride semiconductor layer to have a single crystal plane.

The semiconductor layer 200 may be deposited on the upper portion of the middle layer 300. The semiconductor layer 200 may be a nitride semiconductor layer having a single crystal plane.

In the thin film growth process step, the semiconductor layer 200 may be deposited by ion beam sputtering, in which the substrate 100 is irradiated with ion beams.

For example, step S220 of growing a nitride thin film and step S230 in which the semiconductor layer 200 is irradiated with ion beams may be performed simultaneously.

According to one embodiment, the ion beam sputtering may be performed using at least one of helium (He), neon (Ne), argon (Ar), krypton (Kr), xenon (Xe), radon (Rn), hydrogen (H₂), oxygen (O₂), nitrogen (N₂), chlorine (Cl₂), and ammonia (NH₃).

According to one embodiment, the sputtering target used for the ion beam sputtering may include gallium (Ga) or gallium nitride (GaN).

When the semiconductor layer 200 is deposited, the substrate 100 is irradiated with ion beams at the thin film growth stage, thereby increasing the surface mobility of growing gallium and nitrogen particles.

When the surface mobility of gallium and nitrogen particles being grown is increased by ion beam irradiation, energy required for thin film crystal growth is relatively reduced, so the temperature of the substrate 100 may be kept low.

For example, ion beam sputtering may maintain the temperature of the substrate 100 below 600° C. at the thin film growth stage.

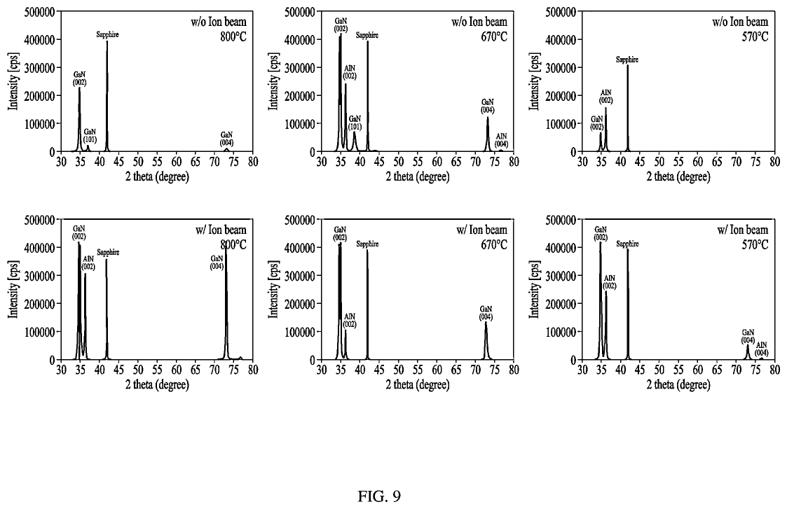

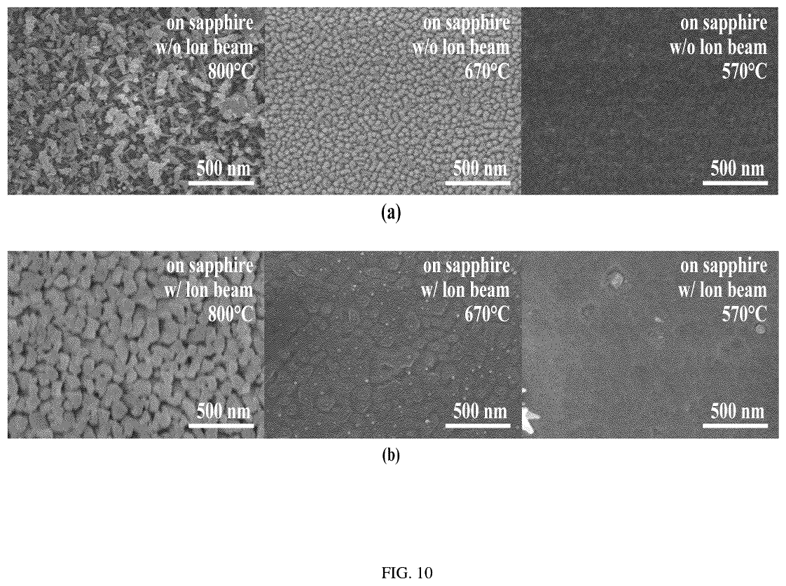

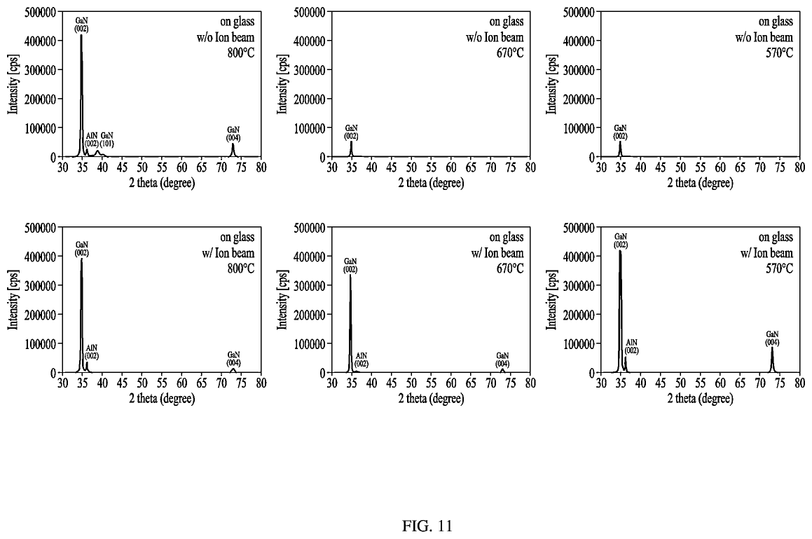

FIG. 9 includes XRD analysis graphs comparing the growth of the semiconductor layer 200 on a sapphire substrate depending on the presence or absence of additional energy, and FIG. 10 includes optical images of the semiconductor layer 200 corresponding to the XRD analysis graphs of FIG. 9.

Referring to FIG. 9, in the case of the upper graphs where ion beams are not supplied as additional energy, the GaN (101) growth and GaN (002) growth rates are lower compared to the lower graphs where ion beams are supplied as additional energy.

In addition, in the case of the graphs at the bottom where ion beams are supplied as additional energy, it can be seen that c-axis growth is clearly visible even in low-temperature thin film deposition at 670° C. and 570° C.

In addition, as shown in FIG. 10, in the case of the lower optical images where ion beams are supplied as additional energy, it can be seen that a flat and uniform GaN thin film is formed compared to the upper optical images where ion beams are not supplied as additional energy.

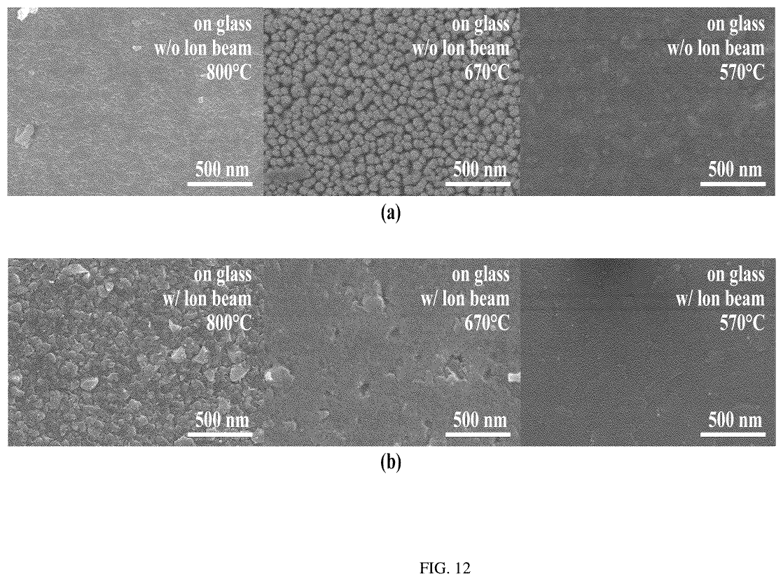

FIG. 11 includes XRD analysis graphs comparing the growth of the semiconductor layer 200 on a glass substrate depending on the presence or absence of additional energy, and FIG. 12 includes optical images of semiconductor layer 200 corresponding to the XRD analysis graphs of FIG. 11.

Referring to FIG. 11, since the semiconductor substrate 10 of the present invention may minimize the thin film growth temperature, the semiconductor layer 200 may be deposited on a glass substrate with a strain temperature of 650° C. or lower.

In the case of the lower graphs where ion beams are supplied as additional energy on a glass substrate, it can be seen that the directionality of GaN (002) is increased compared to the upper graphs where ion beams are not supplied as additional energy.

As shown in FIG. 12, in the case of the lower optical images where ion beams are supplied as additional energy on the glass substrate, it can be seen that the surface is arranged homogeneously compared to the upper optical images where ion beams are not supplied as additional energy.

That is, when ion beams are supplied as additional energy to the glass substrate, the kinetic energy of ions promotes the diffusion of surface atoms, so the thin film surface of the semiconductor layer 200 becomes homogeneous.

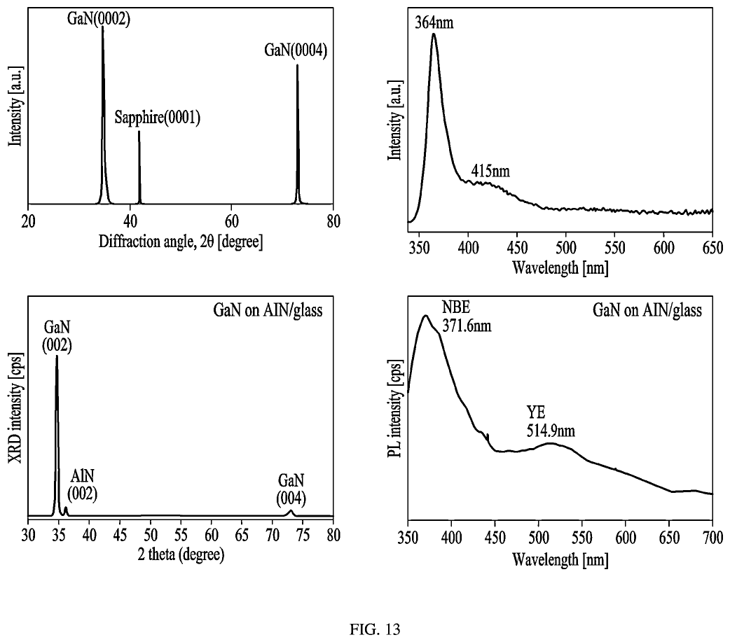

FIG. 13 includes graphs comparing the semiconductor layer 200 of the method according to the present invention in which additional energy is applied through the sputtering method and the semiconductor layer 200 of the conventional MOCVD method.

Referring to FIG. 13, in the case of the conventional MOCVD method, thin film growth occurs at 1030° C. On the other hand, according to the present invention, thin film growth occurs at a low temperature of 570° C.

According to the present invention, since the temperature of thin film growth is lower compared to conventional processes, glass substrates, quartz substrates, stainless steel substrates, and polymer substrates with strain temperatures of 650° C. or lower may be used in the process of forming the semiconductor layer 200 film.

In addition, the semiconductor substrate 10 of the present invention may be applied to various semiconductor-based applications.

For example, the semiconductor substrate 10 of the present invention may be applied to light-emitting diodes (LEDs), power semiconductor devices, thin-film transistors, solar cells, etc.

In particular, when the semiconductor substrate 10 of the present invention is applied to a micro-LED display, production costs due to the light-emitting element chip production and the transfer process are reduced, so the manufacturing cost of large displays containing micro LEDs, such as large-area 4K Micro-LED TVs, may be dramatically reduced.

The apparatus described above may be implemented as a hardware component, a software component, and/or a combination of hardware components and software components. For example, the apparatus and components described in the embodiments may be achieved using one or more general purpose or special purpose computers, such as, for example, a processor, a controller, an arithmetic logic unit (ALU), a digital signal processor, a microcomputer, a field programmable gate array (FPGA), a programmable logic unit (PLU), a microprocessor, or any other device capable of executing and responding to instructions. The processing device may execute an operating system (OS) and one or more software applications executing on the operating system. In addition, the processing device may access, store, manipulate, process, and generate data in response to execution of the software. For ease of understanding, the processing apparatus may be described as being used singly, but those skilled in the art will recognize that the processing apparatus may include a plurality of processing elements and/or a plurality of types of processing elements. For example, the processing apparatus may include a plurality of processors or one processor and one controller. Other processing configurations, such as a parallel processor, are also possible.

Although the present invention has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

1. A semiconductor substrate, comprising:
a substrate; and
a semiconductor layer disposed on an upper portion of the substrate,
wherein the semiconductor layer is deposited by supplying additional energy through sputtering in a thin film growth process step,
wherein the additional energy comprises at least one of ion beams, electron beams, plasma, ultraviolet lights, lasers, and LED light.

2. The semiconductor substrate according to claim 1, wherein the substrate is a glass substrate,
the semiconductor layer is a nitride semiconductor layer having a single crystal plane, and
the semiconductor layer is deposited by ion beam sputtering, which uses the ion beams as the additional energy.

3. The semiconductor substrate according to claim 2, wherein the ion beam sputtering is performed using at least one of helium (He), neon (Ne), argon (Ar), krypton (Kr), xenon (Xe), radon (Rn), hydrogen (H₂), oxygen (O₂), nitrogen (N₂), chlorine (Cl₂), and ammonia (NH₃).

4. The semiconductor substrate according to claim 2, wherein a sputtering target used for the ion beam sputtering comprises gallium (Ga) or gallium nitride (GaN).

5. The semiconductor substrate according to claim 2, wherein, in the thin film growth process step, a deposition temperature of the semiconductor layer is 600° C. or lower.

6. The semiconductor substrate according to claim 1, wherein the substrate comprises at least one of an amorphous substrate and a polycrystalline substrate.

7. The semiconductor substrate according to claim 6, wherein the substrate comprises at least one of a glass substrate, a quartz substrate, a stainless steel substrate, and a polymer substrate.

8. The semiconductor substrate according to claim 1, wherein the semiconductor layer is a silicon semiconductor layer having any one of polycrystalline, microcrystalline, and nanocrystalline crystal structures.

9. The semiconductor substrate according to claim 1, wherein the semiconductor layer is an InGaZnO-based oxide semiconductor layer.

10. The semiconductor substrate according to claim 1, wherein the semiconductor layer is a CuInSe₂-based group 1-3-5 compound semiconductor layer.

11. The semiconductor substrate according to claim 1, further comprising a middle layer disposed between the substrate and the semiconductor layer and consisting of at least one of aluminum nitride and zinc oxide.

12. A semiconductor thin film deposition apparatus, comprising:
a thin film deposition device for growing a nitride semiconductor layer having a single crystal plane on an upper portion of a substrate through sputtering; and
an energy supplier for supplying additional energy of at least one of ion beams, electron beams, plasma, ultraviolet lights, lasers, and LED light to the substrate,
wherein the energy supplier supplies the additional energy to the substrate while the thin film deposition device grows the nitride semiconductor layer on an upper portion of the substrate.
